(19) United States
(12) Patent Application Publication
(10) Pub. No.: US 2019/0341554 A1
(43) Pub. Date: Nov. 7, 2019

(54) LIGHT-EMITTING ELECTROCHEMICAL CELL AND COMPOSITION FOR FORMING LIGHT-EMITTING LAYER OF LIGHT-EMITTING ELECTROCHEMICAL CELL

(71) Applicant: Nippon Chemical Industrial Co., Ltd., Tokyo (JP)

(72) Inventors: Fumihiro Yonekawa, Tokyo (JP); Shizuka Tane, Tokyo (JP)

(73) Assignees: Nippon Chemical Industrial Co., Ltd., Tokyo (JP); Nippon Chemical Industrial Co., Ltd., Tokyo (JP)

(21) Appl. No.: 16/480,135

(22) PCT Filed: Feb. 13, 2018
(86) PCT No.: PCT/JP2018/004867

§ 371 Date: Jul. 23, 2019

(30) Foreign Application Priority Data
Feb. 17, 2017 (JP) 2017-028393

(51) Int. Cl. H01L 51/00; H01L 51/50; C09K 11/06

(52) U.S. Cl. CPC H01L 51/0067; H01L 51/5032; C09K 2211/1018; C09K 11/06; H01L 51/0042

(57) ABSTRACT

A light-emitting electrochemical cell (10) has: a light-emitting layer (12) containing a polymer material having a function of transporting electrons and holes, a light-emitting material emitting light by receiving holes and electrons from the polymer material or emitting light due to excitons generated by combination of holes and electrons on the polymer material, and an electrolyte; and an electrode (13, 14) disposed on each face of the light-emitting layer (12). The light-emitting material is a compound having a pyrromethene skeleton. The light-emitting layer (12) is preferably colorless and transparent in a visible light wavelength region in a state where voltage is not applied.

### TECHNICAL FIELD

The present invention relates to a light-emitting electrochemical cell. The present invention also relates to a composition for forming a light-emitting layer of a light-emitting electrochemical cell.

### BACKGROUND ART

Development of an organic electroluminescent element (hereinafter, also referred to as “organic EL element”), which is an element that spontaneously emits light using an electron and a hole as carriers, has been progressing in recent years. The organic EL element has characteristics such that it is thinner and lighter and has a higher visibility than an element which does not spontaneously emit light and needs back light, such as a liquid crystal element.

Generally, the organic EL element includes: a pair of substrates each having an electrode, the electrode being formed on the respective faces that are opposite to each other; and a light-emitting layer disposed between the pair of substrates. The light-emitting layer includes an organic thin film containing a light-emitting substance that emits light when voltage is applied. In order to allow the organic EL element to emit light, voltage is applied to the organic thin film to inject holes and electrons from an anode and a cathode. Thereby, the holes and the electrons are recombined in the organic thin film, and excitons generated by the recombination return to the ground state, resulting in light emission.

In addition to the light-emitting layer, a hole injection layer and an electron injection layer for improving efficiency of injecting holes and electrons, and a hole transport layer and an electron transport layer for improving efficiency of recombination of holes and electrons need to be provided between the light-emitting layer and the electrode in the organic EL element. Due to this, the structure of the organic EL element, which has a multilayered structure, is complicated, and the number of production processes is increased. In addition, there are many restrictions on the organic EL element because work functions need to be taken into consideration in selecting electrode materials for an anode and for a cathode.

As a self-luminous element that solves these problems, light-emitting electrochemical cells (Light-emitting Electrochemical Cells: LEC) have attracted attention in recent years. A light-emitting electrochemical cell generally has a light-emitting layer containing a salt and an organic light-emitting material. When voltage is applied, cations and anions each derived from the salt move toward a cathode and an anode respectively in the light-emitting layer, and this brings about a large electric field gradient (electric double layer) at electrode interfaces. Due to the electric double layer formed, injection of electrons and holes at the cathode and the anode respectively is easy, and therefore a multilayered structure as in an organic EL element is not necessary in the light-emitting electrochemical cell. In addition, there are fewer restrictions on materials for the light-emitting electrochemical cell because work functions of materials to be used as a cathode and as an anode do not need to be taken into consideration. From these reasons, the light-emitting electrochemical cell is expected as a self-luminous element that can considerably reduce production costs as compared to the organic EL element.

As a conventional technique on the light-emitting electrochemical cell, for example, the techniques described in Patent Literatures 1 and 2 are known. In these literatures, it is disclosed that a pyrromethene-based compound can be used as a light-emitting substance.

### CITATION LIST

### Patent Literature

### Patent Literature 1: US 2013006118 A1

### Patent Literature 2: US 2013324909 A1

### SUMMARY OF INVENTION

Light emission with a high light-emission efficiency and a high luminance is demanded of a light-emitting electrochemical cell. Satisfactory light emission efficiency and luminance cannot be provided by the techniques described in the above-described Patent Literatures.

Accordingly, an object of the present invention is to provide: a light-emitting electrochemical cell that can solve various drawbacks of the above-described conventional techniques; and a composition for a light-emitting layer to be used for the light-emitting electrochemical cell.

The present invention provides a light-emitting electrochemical cell having: a light-emitting layer containing a polymer material having a function of transporting electrons and holes, a light-emitting material that emits light by receiving the holes and the electrons from the polymer material or emits light due to excitons generated by combination of the holes and the electrons on the polymer material, and an electrolyte; and an electrode disposed on each face of the light-emitting layer, wherein the light-emitting material is a compound having a pyrromethene skeleton.

The present invention also provides a composition for forming a light-emitting layer of a light-emitting electrochemical cell, the composition containing: a polymer material having a function of transporting electrons and holes; a light-emitting material emitting light by receiving the holes and the electrons from the polymer material or emitting light due to excitons generated by combination of the holes and the electrons on the polymer material; and an electrolyte, wherein the light-emitting material is a compound having a pyrromethene skeleton.

### BRIEF DESCRIPTION OF DRAWINGS

FIG. 1 is a schematic sectional view of a light-emitting electrochemical cell in one embodiment according to the present invention.

FIG. 2 is a conceptual diagram illustrating a light emission mechanism of a light-emitting electrochemical cell. FIG. 2(a) illustrates a light-emitting electrochemical cell before applying voltage, and FIG. 2(b) illustrates a light-emitting electrochemical cell after applying voltage.

FIG. 3 is a graph showing results of measuring luminance of emitted light of light-emitting electrochemical cells obtained in Examples 1 and 2, and Comparative Example 1.

FIG. 4 is a graph showing results of measuring light emission efficiency of light-emitting electrochemical cells obtained in Examples 1 and 2, and Comparative Example 1.

FIG. 5 is a graph showing a result of measuring visible light transmittance of a light-emitting layer in a light-emitting electrochemical cell obtained in Example 1.

FIG. 6 is a graph showing results of measuring luminance of emitted light of light-emitting electrochemical cells obtained in Examples 3 to 5, and Comparative Example 2.

FIG. 7 is a graph showing results of measuring light emission efficiency of light-emitting electrochemical cells obtained in Examples 3 to 5, and Comparative Example 2.

FIG. 8 is a graph showing a result of measuring visible light transmittance of a light-emitting layer in a light-emitting electrochemical cell obtained in Example 5.

### DESCRIPTION OF EMBODIMENTS

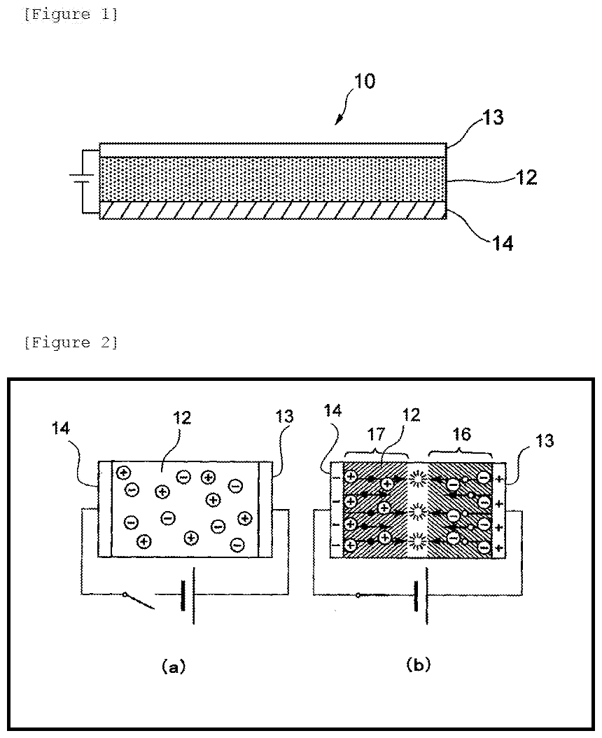

Hereinafter, the present invention will be described based on preferred embodiments thereof. FIG. 1 illustrates a sectional view in a thickness direction, the sectional view illustrating one embodiment of a light-emitting electrochemical cell according to the present invention. As illustrated in FIG. 1, the light-emitting electrochemical cell 10 according to the present embodiment has: a light-emitting layer 12; and an electrode 13, 14 disposed on each face of the light-emitting layer. The light-emitting electrochemical cell 10 is configured so that the light-emitting layer 12 emits light by applying voltage between the electrodes 13, 14. The light-emitting electrochemical cell 10 is suitably used, for example, as various display elements. FIG. 1 illustrates a state in which a DC power source is used as a power source, the first electrode 13 is connected to the positive electrode of the DC power source, and the second electrode 14 is connected to the negative electrode. However, the first electrode 13 may be connected to the negative electrode, and the second electrode 14 may be connected to the positive electrode, which is the reverse of the illustrated figure. An AC power source can be used as a power source in place of the DC power source.

The first electrode 13 and the second electrode 14 may each be a transparent electrode having translucency in a visible light wavelength region or a semitransparent or opaque electrode in a visible light wavelength region. Examples of the transparent electrode having translucency include electrodes formed of a metal oxide such as indium-doped tin oxide (ITO) or fluorine-doped tin oxide (FTO). In addition, examples of the first electrode 13 and the second electrode 14 include electrodes formed of a polymer having transparency, such as impurity-added poly(3,4-ethylenedioxythiophene) (PEDOT). Examples of the semitransparent or opaque electrode include metal materials such as aluminum, silver, gold, platinum, tin, bismuth, copper, and chromium.

It is preferable that at least one of the first electrode 13 and the second electrode 14 be a transparent electrode because light emitted from the light-emitting layer 12 can easily be taken outside. It is also preferable that the one of the electrodes be a transparent electrode and the other be a metal electrode which is opaque because light emitted from the light-emitting layer 12 can be taken outside the cell through the transparent electrode while reflecting the light at the metal electrode. Both of the first electrode 13 and the second electrode 14 may be a transparent electrode to make a see-through light-emitting body. When a metal electrode formed of a material having a high reflectance, such as Ag, is used for both of the first electrode 13 and the second electrode 14 together with the light-emitting layer 12 having a controlled film thickness, the light-emitting electrochemical cell 10 can thereby be made as a laser oscillation element.

In the case where the first electrode 13 and the second electrode 14 are a transparent electrode and a metal electrode which is opaque or semitransparent, respectively, the first electrode 13 preferably has a thickness of, for example, 10 nm or more and 500 nm or less in view of realizing suitable resistivity and light transparency. Similarly to the first electrode 13, the second electrode 14 preferably has a thickness of, for example, 10 nm or more and 500 nm or less in view of realizing suitable resistivity and light transparency.

The light-emitting layer 12 in the light-emitting electrochemical cell 10 is formed of a composition for forming a light-emitting layer, the composition containing a plurality of components mixed therein. The light-emitting layer 12 may be solid or liquid. The light-emitting layer 12 is preferably solid because of the following reasons: a solid can keep a constant shape and resist force applied from the outside; and a stretchable light-emitting electrochemical cell can be prepared by combining a flexible material such as a stretchable electrode with the light-emitting layer 12.

The above-described composition for forming a light-emitting layer contains: (A) a polymer material having a function of transporting electrons and holes; (B) a light-emitting material emitting light by receiving holes and electrons from the polymer material; and (C) an electrolyte. Hereinafter, these components will individually be described.

### (A) Polymer Material

As the polymer material, a polymer material having a function of transporting holes and electrons in the light-emitting layer 12 of the light-emitting electrochemical cell 10 is used. Examples of such a polymer material include polymer materials having π conjugated double bonds through which π electrons are delocalized over a wide range. The polymer material is preferably a polymer material that can transfer energy from the polymer material to a light-emitting material at the time of light emission of the light-emitting layer 12 and, in view of this, is also preferably a substance having a large band gap. In a view of efficient energy transfer, an overlap between the light emission wavelength of the polymer material and the absorption wavelength of the light-emitting material is preferably larger. The polymer material is preferably colorless and transparent in a visible light wavelength region. “Colorless and transparent” mean that when the polymer material is formed into a film having the same thickness as that of the light-emitting layer 12 of the light-emitting electrochemical cell 10, the film has a light transmittance of 70% or more in a visible light region. The visible light region refers to a wavelength region of 450 nm or more and 800 nm or less.

Examples of preferred polymer materials having a function of transporting electrons and holes include a polymer compound having a fluorene skeleton, a polymer compound having a carbazole skeleton, a σ conjugated silicon polymer (polysilane-based polymer such as poly[bis(para-butylphenyl)silane]), and a polyphenylene (such as poly(1,4-phenylene)). As the polymer compound having a fluorene skeleton, poly[(9,9-dioctylfluorenyl-2,7-diyl)-alt-co-(9,9′-spirobifluorene-2,7-diyl)] is preferably used in view of suppressing aggregation of the polymer. As the polymer compound having a carbazole skeleton, poly(N-vinylcarbazole) is preferably used. These polymer materials can be used singly or in combinations of two or more thereof.

The amount of the polymer material in the composition forming the light-emitting layer 12 is preferably 60 parts by mass or more and 98 parts by mass or less, more preferably 70 parts by mass or more and 95 parts by mass or less, and still more preferably 80 parts by mass or more and 92 parts by mass or less per 100 parts by mass of the total amount of the light-emitting layer 12 in view of keeping the function of transporting holes and electrons and of retaining the physical strength as a light-emitting layer of a solid.

### (B) Light-Emitting Material

As the light-emitting material, a material that emits light by receiving holes and electrons from the polymer material (A), or a material that emits light due to excitons generated by combination of holes and electrons on the polymer material is used. As such a material, a compound having a pyrromethene skeleton is used in the present invention. It is known that the compound having a pyrromethene skeleton is used in various light-emitting devices including a light-emitting electrochemical cell; however, the present inventor is the first to attempt to use the compound having a pyrromethene skeleton as the light-emitting material that emits light by receiving holes and electrons from the polymer material having a function of transporting electrons and holes or emits light due to excitons generated by combination of holes and electrons on the polymer material. The present inventor has surprisingly found that by using the compound having a pyrromethene skeleton as a light-emitting material of a light-emitting electrochemical cell, a light-emitting electrochemical cell that emits light with a high light emission efficiency and a high luminance is obtained.

Particularly, the compound having a pyrromethene skeleton is preferably a complex of the compound having a pyrromethene skeleton in view of obtaining a light-emitting electrochemical cell of a high light emission efficiency and a high luminance. A complex represented by the following formula 1 is particularly preferably used as the compound having a pyrromethene skeleton.

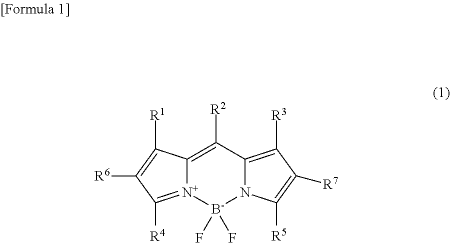

wherein, R¹ to R⁷ are the same or different from one another and each independently represent a hydrogen atom or an alkyl group.

In the compound represented by formula 1, each of the alkyl groups represented by R¹ to R⁷ is preferably a hydrogen atom or a straight-chain or branched-chain alkyl group having 1 to 8 carbon atoms. More preferably, each of the alkyl groups represented by R¹ to R⁷ is a hydrogen atom or a straight-chain or branched-chain alkyl group having 1 to 6 carbon atoms, and still more preferably a hydrogen atom or a straight-chain or branched-chain alkyl group having 1 to 4 carbon atoms. In view of obtaining a light-emitting electrochemical cell of an even higher light emission efficiency and even higher luminance, it is preferable that among R¹ to R⁷, each of R¹ to R⁵ be the same alkyl group, and each of R⁶ and R⁷ be the same alkyl group but be an alkyl group that is different from R¹ to R⁵. From the same viewpoint, it is also preferable that among R¹ to R⁷, each of R¹ to R⁵ be the same alkyl group, and each of R⁶ and R⁷ be a hydrogen atom. Among others, it is preferable that among R¹ to R⁷, each of R¹ to R⁵ be the same alkyl group, and each of R⁶ and R⁷ be the same alkyl group having a larger number of carbon atoms than R¹ to R⁵ or having a smaller number of carbon atoms than R¹ to R⁵ in view of obtaining a light-emitting electrochemical cell of a still even higher light emission efficiency and still even higher luminance.

As a specific example of R¹ to R⁷, it is preferable that each of R¹ to R⁵ be a methyl group, and each of R⁶ and R⁷ be the same straight-chain or branched-chain butyl group. It is preferable that each of R¹ to R⁵ be a methyl group, and each of R⁶ and R⁷ be a hydrogen atom.

Examples of particularly preferable compounds each having a pyrromethene skeleton include 1,3,5,7,8-pentamethylpyrromethene-difluoroborate complex, 1,3,5,7,8-pentamethyl-2,6-di-t-butylpyrromethene-difluoroborate complex, 1,3,5,7,8-pentamethyl-2,6-di-n-butylpyrromethene-difluoroborate complex, and 1,3,5,7,8-pentamethyl-2,6-diethylpyrromethene-difluoroborate complex. Among these, 1,3,5,7,8-pentamethylpyrromethene-difluoroborate complex, 1,3,5,7,8-pentamethyl-2,6-di-t-butylpyrromethene-difluoroborate complex, and 1,3,5,7,8-pentamethyl-2,6-di-n-butylpyrromethene-difluoroborate complex are further preferable.

The compound having a pyrromethene skeleton, which is to be used as a light-emitting material, is a substance of a high light emission efficiency, and therefore a sufficient luminance can be obtained by adding it in a small amount. In view of this, the amount of the light-emitting material in the composition forming the light-emitting layer 12 is preferably 0.1 parts by mass or more and 15 parts by mass or less, more preferably 1 part by mass or more and 10 parts by mass or less, and still more preferably 2 parts by mass or more and 8 parts by mass or less per 100 parts by mass of the total amount of the light-emitting layer 12. Addition in such a small amount makes it easy to make the light-emitting layer 12 colorless and transparent in a visible light wavelength region in a state where voltage is not applied. Allowing the light-emitting layer 12 to be colorless and transparent in a visible light wavelength region in a state where voltage is not applied contributes to widening the field of application of the light-emitting electrochemical cell 10. For example, in the case where the first electrode 13 and the second electrode 14 are a transparent electrode and a light-reflecting metal electrode, respectively, and used together with the light-emitting layer 12 that is colorless and transparent, the light-emitting electrochemical cell 10 can be utilized as a mirror when voltage is not applied, and can be utilized as a display element when voltage is applied.

The phrase “the light-emitting layer 12 is colorless and transparent in a visible light wavelength region” means that the light transmittance of the light-emitting layer 12 in the visible light wavelength region is 70% or more. The method for measuring the light transmittance of the light-emitting layer 12 will be described later.

### (C) Electrolyte

As the electrolyte, a substance is suitably used that can secure the mobility of ions, easily form an electric double layer, and easily inject holes and electrons in the light-emitting layer 12. As such a substance, an ionic compound is preferably used. As the ionic compound, a compound containing a cation and an anion can be used. Any of a salt of an organic cation and a salt of an inorganic cation can be adopted as the ionic compound. As the salt of an organic cation, a salt in which the cation is a phosphonium cation, an ammonium cation, a pyridinium cation, an imidazolium cation, or a pyrrolidinium cation, or the like can be used. Preferred examples of the salt of an inorganic cation include salts of a metal cation of group 1 or group 2.

The ionic compound may be any of an organic salt and an inorganic salt. Examples of the organic salt include the above-described salts of the organic cations and salts consisting of an inorganic cation and an organic anion. In the case of the inorganic salt, those in which the cation is any of the above-described metal cations, such as a lithium ion or a potassium ion, can be used. Among others, at least one selected from a phosphonium cation, an ammonium cation, and an imidazolium cation is preferably used as the cation in view of high compatibility with the light-emitting material. Particularly, in view of easily obtaining a high luminance at a low voltage in the case where the ionic compound is used together with any of the above-described light-emitting material, at least one selected from a phosphonium cation and an ammonium cation is preferably used as the cation for the ionic compound for the light-emitting layer 12.

Examples of the ionic compound in which the cation is a phosphonium cation or an ammonium cation include a compound represented by the following formula 2.

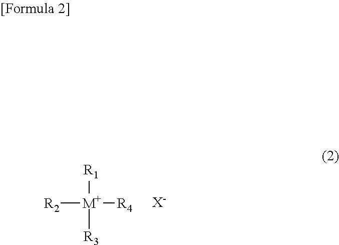

wherein R₁, R₂, R₃, and R₄ each represent an alkyl group, an alkoxyalkyl group, a trialkylsilylalkyl group, an alkenyl group, an alkynyl group, an aryl group, or a heterocyclic group which is optionally substituted with a functional group. R₁, R₂, R₃, and R₄ may be the same with or different from one another. M represents N or P. X⁻ represents an anion.

Each of the alkyl groups represented by R₁, R₂, R₃, and R₄ may be any of a branched-chain alkyl group, a straight-chain alkyl group, and a cyclic alkyl group, but a branched-chain alkyl group or a straight-chain alkyl group are preferable. Examples of the branched-chain or straight-chain alkyl group include a methyl group, an ethyl group, an n-propyl group, an isopropyl group, an n-butyl group, an s-butyl group, a t-butyl group, an isobutyl group, an n-amyl group, an isoamyl group, a t-amyl group, an n-hexyl group, an n-heptyl group, an isoheptyl group, a t-heptyl group, an n-octyl group, an isooctyl group, a 2-ethylhexyl group, a t-octyl group, a nonyl group, an isononyl group, a decyl group, an isodecyl group, an undecyl group, a dodecyl group, a tridecyl group, an isotridecyl group, a tetradecyl group, a hexadecyl group, an octadecyl group, and an icosyl group. Examples of the cyclic alkyl group include a cyclopentyl group, a cyclohexyl group, and a group in which at least one hydrogen atom thereof is replaced with any of the above-described chain aliphatic hydrocarbon groups.

Examples of the alkoxyalkyl groups represented by R₁, R₂, R₃, and R₄ include alkoxides of the above-described alkyl groups.

Examples of the alkyl croups in the trialkylsilylalkyl groups represented by R₁, R₂, R₃, and R₄ include the above-described alkyl groups.

Examples of the alkenyl groups and the alkynyl groups each represented by R₁, R₂, R₃, and R₄ include: straight-chain or branched-chain alkenyl groups such as a vinyl group, an allyl group, an isopropenyl group, a 2-butenyl group, a 2-methylallyl group, a 1,1-dimethylallyl group, a 3-methyl-2-butenyl group, a 3-methyl-3-butenyl group, a 4-pentenyl group, a hexenyl group, an octenyl group, a nonenyl group, and a decenyl group; and alkynyl groups such as an ethynyl group, and a prop-2-yn-1-yl group.

Examples of the aryl groups represented by R₁, R₂, R₃, and R₄ include a phenyl group, a napththyl group, an anthracenyl group, and groups in which at least one hydrogen atom bonded to any of these aromatic rings is replaced with a chain aliphatic hydrocarbon group, such as a tolyl group and a xylyl group. In addition, examples of the heterocyclic groups represented by R₁, R₂, R₃, and R₄ include monovalent groups derived from pyridine, pyrrole, furan, imidazole, pyrazole, oxazole, imidazoline, pyrazine, and the like.

At least one of the hydrogen atoms contained in each of the groups described above as the groups represented by R₁, R₂, R₃, and R₄ may be replaced with a functional group. Examples of the functional group include a halogen atom, an amino group, a nitrile group, a phenyl group, a benzyl group, a carboxyl group, and an alkoxy group having 1 to 12 carbon atoms.

Part of the hydrogen atoms contained in each of the groups described above as the groups represented by R₁, R₂, R₃, and R₄ may be replaced with a fluorine atom. Voltage endurance is improved by introducing a fluorine atom, leading to the stability and long service life of the light-emitting electrochemical cell.

As the ionic compound in which the cation is a phosphonium cation or an ammonium cation, at least one group among R₁, R₂, R₃, and R₄ is preferably an alkyl group, and each of R₁, R₂, R₃, and R₄ is more preferably an alkyl group in view of compatibility with the compound represented by formula 2 and obtaining a high luminance and also in view of the compatibility with the light-emitting material and voltage endurance. In view of further improving the compatibility between the ionic compound and the light-emitting material, the number of carbon atoms of the alkyl groups represented by R₁, R₂, R₃, and R₄ is preferably 2 or mere and 18 or less, and more preferably 4 or more and 8 or less.

Particularly in the case where 2, 3, or 4 alkyl groups among the alkyl groups represented by R₁, R₂, R₃, and R₄ are alkyl groups each having the same number of carbon atoms, the number of carbon atoms of the alkyl groups each having the same number of carbon atoms is preferably 2 or more and 18 or less, and more preferably 4 or more and 8 or less in the view of the above.

The molecular weight of the phosphonium cation or the ammonium cation in the compound represented by formula 2 is preferably 150 or more and 750 or less, particularly 200 or more and 500 or less, and 250 or more and 350 or less among others because the luminance of emitted light of the light-emitting electrochemical cell is further higher and the luminance of emitted light is further excellent.

In view of securing the ion mobility and enhancing the film-forming property of the light-emitting layer 12, the content of the ionic compound in the composition constituting the light-emitting layer 12 is preferably 1 part by mass or more and 20 parts by mass or less, and more preferably 2 parts by mass or more and 10 parts by mass or less per 100 parts by mass of the total amount of the light-emitting layer 12. In addition, the content of the ionic compound in the light-emitting layer 12 is preferably 1 part by mass or more and 25 parts by mass or less per 100 parts by mass of the light-emitting material.

### (D) Additional Component

An additional component other than the polymer material, the light-emitting material, and the electrolyte may be contained in the light-emitting layer 12. Examples of such a substance include a surfactant, a polymer component (such as polystyrene or polymethylmethacrylate (PMMA)) for improving a film-forming property, and a component capable of improving the compatibility among the polymer material, the light-emitting material, and the electrolyte to improve film quality (phosphoric acid esters such as tris(2-ethylhexyl)phosphate and tributyl phosphate and carboxylic acid esters such as dibutyl phthalate, diisononyl phthalate, and bis(2-ethylhexyl) phthalate). As the component capable of improving the compatibility between the light-emitting material and the electrolyte to improve film quality, dibutyl phthalate is preferably used because it is an organic compound having voltage endurance enough to dissolve the light-emitting material and the electrolyte. The amount of the additional component (excluding solvent) is preferably 30 parts by mass or less, more preferably 20 parts by mass or less, and still more preferably 10 parts by mass or less per 100 parts by mass of the total amount of the light-emitting layer 12.

The film thickness of the light-emitting layer 12 formed of the composition containing the above-described respective components is preferably 20 nm or more and 300 nm or less, and more preferably 50 nm or more and 150 nm or less. The film thickness of the light-emitting layer 12 is preferably in this range because of the following reasons: light emission can be obtained sufficiently and efficiently from the light-emitting layer 12, and a defect at a predetermined light-emitting portion can be suppressed, resulting in short circuit prevention.

The light-emitting electrochemical cell 10 according to the present embodiment can suitably be produced, for example, by the following production method. A substrate having the first electrode 13 is first provided. In the case where the first electrode 13 is formed from, for example, ITO (indium-doped tin oxide), a vapor-deposited film of ITO may be formed in a pattern on the surface of a glass substrate or the like using a photolithography method or using a photolithography method and a lift-off method in combination.

Next, the polymer material having a function of transporting electrons and holes, the light-emitting material emitting light by receiving holes and electrons from the polymer material, and the electrolyte are dissolved or dispersed in an organic solvent to prepare a composition for forming a light-emitting layer of a light-emitting electrochemical cell. In view of, for example, efficiently mixing the polymer material having a function of transporting electrons and holes, the light-emitting material emitting light by receiving holes and electrons from the polymer material, and the electrolyte, the organic solvent preferably contains at least one organic solvent selected from the group consisting of toluene, benzene, xylene, tetrahydrofuran, dimethyl chloride, cyclohexanone, monochlorobenzene, dichlorobenzene, and chloroform. In this case, as the organic solvent, only one of these compounds or a mixture consisting of two or more of these compounds can be used. Alternatively, these can be used mixing another organic solvent such as methanol or ethanol as long as the characteristics, such as solubility, of these compounds are not impaired. That is, the organic solvent that dissolves or disperses the polymer material having a function of transporting electrons and holes, the light-emitting material emitting light by receiving holes and electrons from the polymer material, and the electrolyte can contain: at least one organic solvent selected from the group consisting of toluene, benzene, xylene, tetrahydrofuran, dimethyl chloride, cyclohexanone, monochlorobenzene, dichlorobenzene, and chloroform; and an organic solvent other than these organic solvents.

The above-described composition for forming a light-emitting layer is applied on the first electrode 13 of the substrate by a thin film-forming method such as a spin coating method. Thereafter, a coating film formed by this application is dried to remove the organic solvent to form the light-emitting layer 12. Preparation of the composition for forming a light-emitting layer and formation of the light-emitting layer 12 are preferably performed in an inert gas atmosphere preferably having a water content of 100 ppm or less. As the inert gas in this case, argon, nitrogen, helium, or the like is suitably used.

Next, the second electrode 14 is formed on the surface of the formed light-emitting layer 12. For example, aluminum can be vapor-deposited in the form of a film on the light-emitting layer 12 through a mask by a vacuum vapor deposition method or the like. Thereby, the second electrode 14 having a predetermined pattern can be formed. By the above-described operation, the light-emitting electrochemical cell 10 having a structure illustrated in FIG. 1 is obtained.

The light-emitting electrochemical cell 10 according to the present embodiment emits light by the following light emission mechanism. For example, as illustrated in FIGS. 2(a) and (b), voltage is applied to the light-emitting layer 12 so that the first electrode 13 is an anode, and the second electrode 14 is a cathode. As a result, ions in the light-emitting layer 12 move along the electric field, so that a layer in which anionic species gather is formed in the vicinity of the interface of the light-emitting layer 12 with the first electrode 13. On the other hand, a layer in which cationic species gather is formed in the vicinity of the interface of the light-emitting layer 12 with the second electrode 14. In this way, an electric double layer is formed at the interface of each electrode. Thereby, a p-doped region 16 is formed spontaneously in the vicinity of the first electrode 13 which is the anode, and an n-doped region 17 is formed spontaneously in the vicinity of the second electrode 14 which is the cathode. These doped regions constitute a p-i-n junction having a high carrier density. Thereafter, holes and electrons are injected into the p-doped region and the n-doped region of the light-emitting layer 12 from the anode and the cathode respectively. Holes and electrons are recombined in the i layer. Excitons are generated from the recombined holes and electrons, and when these excitons return to the ground state, light is thereby emitted from the light-emitting material. In this way, light emission is obtained from the light-emitting layer 12. To obtain light of desired wavelength, a light-emitting material having an energy difference (band gap) between the highest occupied molecular orbital and the lowest unoccupied molecular orbital, the energy difference corresponding to the desired wavelength, may be selected.

### EXAMPLES

Hereinafter, the present invention will be described in more detail with reference to Examples. However, the scope of the present invention is not limited to these Examples. The symbol “%” means “% by mass” unless otherwise noted.

### Example 1

The light-emitting electrochemical cell 10 having a structure illustrated in FIG. 1 was produced. A commercially available glass substrate with an ITO film (manufactured by GEOMATEC Co., Ltd., ITO film thickness of 200 nm) was used as the first electrode 13.

The polymer material, the ionic compound, and pyrromethene 546 (1,3,5,7,8-pentamethylpyrromethene-difluoroborate complex) as the light-emitting material, which are shown in Table 1 below, were used to prepare a mixed solution thereof. Specifically, a composition for forming a light-emitting layer was prepared by mixing a monochlorobenzene solution of the polymer material (concentration: 9 g/L), a monochlorobenzene solution of the ionic compound (concentration: 9 g/L), and a monochlorobenzene solution of pyrromethene 546 (concentration: 4.5 g/L) in a mass ratio of polymer material solution:ionic compound solution:pyrromethene 546 solution=80:15:5 in an argon atmosphere in a glove box at room temperature.

Next, the above-prepared composition for forming a light-emitting layer was applied on the first electrode 13 of the glass substrate by spin coating to form a film in an argon atmosphere in a glove box at room temperature. Further, the glass substrate was heated on a hot plate of 80° C. for 30 minutes to evaporate monochlorobenzene. In this way, a light-emitting layer 12 having a film thickness of 100 nm in the form of a solid was formed.

Further, the second electrode 14 made of aluminum and having a thickness of 50 nm was formed on the formed light-emitting layer 12 by a vapor deposition method. In this way, the light-emitting electrochemical cell 10 in which the area of a predetermined light-emitting portion is 2 mm×2 mm square was produced.

### Example 2

The same operation as in Example 1 was performed except that pyrromethene 597 (1,3,5,7,8-pentamethyl-2,6-di-t-butylpyrromethene-difluoroborate complex) was used in place of pyrromethene 546 as the light-emitting material in Example 1. A monochlorobenzene solution of pyrromethene 597 was prepared at room temperature. The concentration of the monochlorobenzene solution of pyrromethene 597 was set to 9 g/L. In this way, a composition for forming a light-emitting layer was prepared, and a light-emitting electrochemical cell was produced using this composition.

### Example 3

A composition for forming a light-emitting layer was prepared in the manner as described below in Example 1. The composition for forming a light-emitting layer was prepared by mixing a monochlorobenzene solution of the ionic compound (concentration: 18 g/L), a monochlorobenzene solution of pyrromethene 546 (concentration: 4.5 g/L), and a cyclohexanone solution of dibutyl phthalate (concentration: 18 g/L) as an additive with the polymer material shown in Table 1 in a mass ratio of polymer material solution:ionic compound solution:pyrromethene 546 solution:additive solution=47.5:23.75:23.75:5. In addition, a glass substrate on which the composition for forming a light-emitting layer was applied was heated to evaporate monochlorobenzene and cyclohexanone. The light-emitting electrochemical cell 10 was produced in the same manner as in Example 1, excluding those described above.

### Example 4

The same operation as in Example 3 was performed except that pyrromethene 580 (1,3,5,7,8-pentamethyl-2,6-di-n-butylpyrromethene-difluoroborate complex) was used in place of pyrromethene 546 as the light-emitting material in Example 3. A monochlorobenzene solution of pyrromethene 580 was prepared at room temperature. The concentration of the monochlorobenzene solution of pyrromethene 580 was set to 9 g/L. In this way, a composition for forming a light-emitting layer was prepared, and a light-emitting electrochemical cell was produced using this composition.

### Example 5

The same operation as in Example 1 was performed except that pyrromethene 597 (1,3,5,7,8-pentamethyl-2,6-di-t-butylpyrromethene-difluoroborate complex) was used in place of pyrromethene 546 as the light-emitting material in Example 3. A monochlorobenzene solution of pyrromethene 597 was prepared at room temperature. The concentration of the monochlorobenzene solution of pyrromethene 597 was set to 9 g/L. In this way, a composition for forming a light-emitting layer was prepared, and a light-emitting electrochemical cell was produced using this composition.

### Comparative Example 1

The same operation as in Example 1 was performed except that pyrromethene 546 was not added in Example 1. In this way, a composition for forming a light-emitting layer was prepared, and a light-emitting electrochemical cell was produced using this composition.

### Comparative Example 2

The same operation as in Example 3 was performed except that pyrromethene 546 was not added in Example 3. In this way, a composition for forming a light-emitting layer was prepared, and a light-emitting electrochemical cell was produced using this composition.

Evaluation

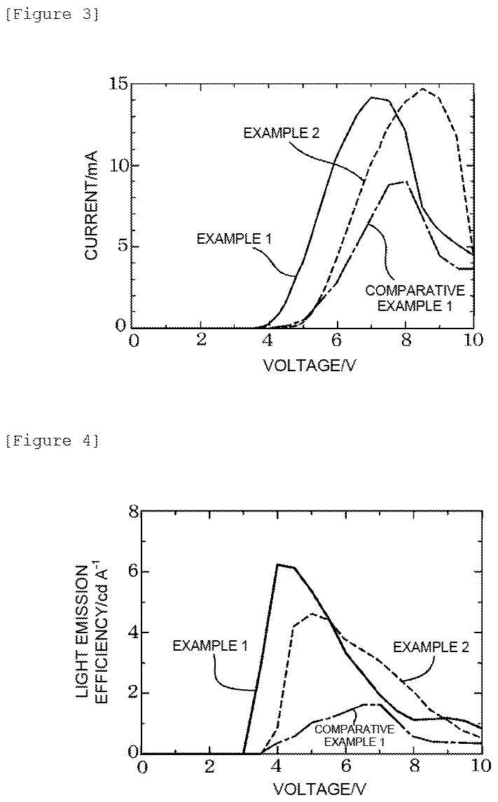

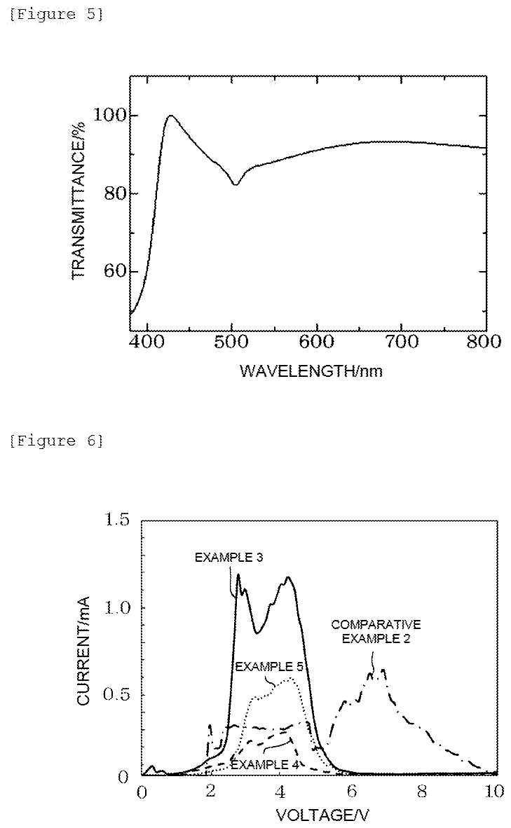

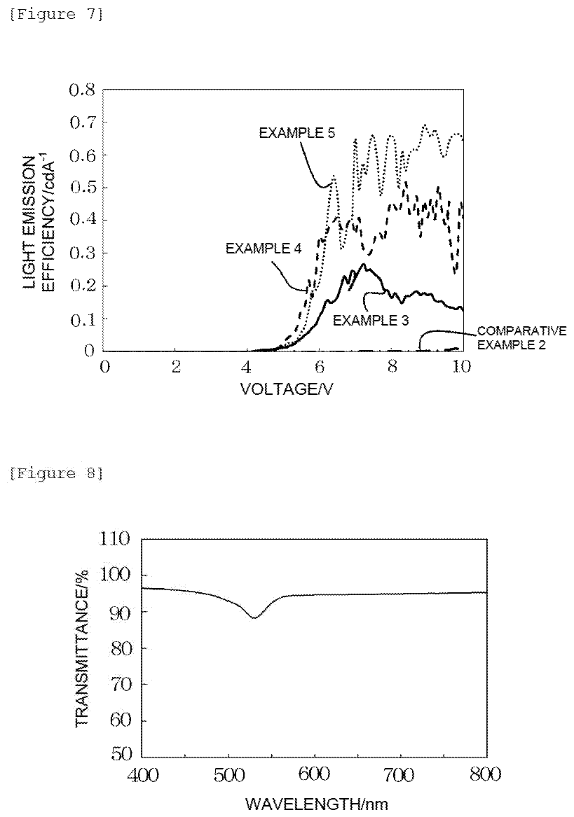

The luminance of emitted light of each of the light-emitting electrochemical cells obtained in Examples and Comparative Examples was measured. The results are shown in Table 1 below. In addition, a change in a current with time of each of the light-emitting electrochemical cells obtained in Examples and Comparative Examples was measured. The results are shown in FIG. 3 and FIG. 6. Further, the light emission efficiency of each of the light-emitting electrochemical cells obtained in Examples and Comparative Examples was measured. The results are shown in FIG. 4 and FIG. 7. Furthermore, results of measuring the transmittance of each light-emitting layer of the light-emitting electrochemical cells obtained in Examples 1 and 5 are shown in FIG. 5 and FIG. 8. The luminance of emitted light, the change in a current with time, the light emission efficiency, and the transmittance were measured by the following methods.

### Luminance of Emitted Light, Change in Current with Time, and Light Emission Efficiency

The first electrode of a light-emitting electrochemical cell was connected to the positive electrode of a DC power source, and the second electrode was connected to the negative electrode. Voltage was linearly swept from 0 V to 10 V over 60 seconds, and the maximum value of luminance during sweeping the voltage was defined as the luminance of emitted light. In addition, the change in a current with time on that occasion was measured. Further, the light emission efficiency (cd/A) was calculated based on a light emission area (m²) and a current value (A) at the luminance (cd/m²). The measurement was conducted using LS-110 manufactured by KONICA MINOLTA, INC.

### Transmittance

The transmittance of each light-emitting layer in a wavelength region of 450 nm or more and 800 nm or less was measured after the light-emitting layer 12 was formed and before the second electrode 14 was formed in the light-emitting electrochemical cell production process. The measurement was conducted using a spectrophotometer U-2910 manufactured by Hitachi High-Technologies Corporation. A glass substrate with an ITO film (manufactured by GEOMATEC Co., Ltd., ITO film thickness of 200 nm) was used as a blank.

TABLE 1

| | Light-emission characteristics | | | Organic | | | |
|---|---|---|---|---|---|---|---|
| | Luminance | | | polymer | Color of | | |
| | of emitted | | | light-emitting | emitted | Ionic compound | |
| | light (cd/m²) | Voltage (V) | Pyrromethene | material | light | Cation | Anion |
| Example 1 | 9,000 | 6.0 | 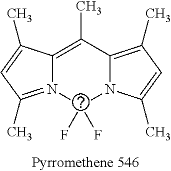 | PFO-spiro¹⁾ | Green | P(C₄H₉-n)₄* | PO₂(OC₄H₉-n)₂* |
| Example 2 | 8,000 | 7.0 | 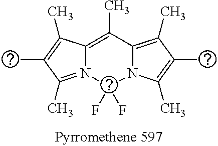 | | Yellow | | |
| Comparative | 3,000 | 7.0 | Not added | | Blue | | |
| Example 1 | | | | | | | |
| Example 3 | 1.35 | 10.0 | 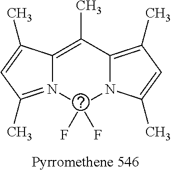 | PVK²⁾ | Green | P(C₄H₉-n)₄* | PO₂(OC₄H₉-n)₂* |
| Example 4 | 1.04 | 4.4 | 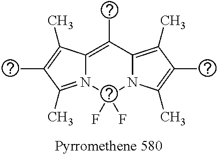 | | Green | | |
| Example 5 | 1.92 | 10.0 | 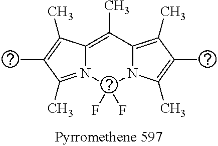 | | Yellow | | |
| Comparative | 0.51 | 5.0 | Not added | | Blue | | |
| Example 2 | | | | | | | |

¹⁾PFO-spiro ... (Polyl(9,9-dioctylfluorenyl-2,7-diyl)-alt-co-(9,9′-spirobifluorene-2,7-diyl)], manufactured by Solaris Chem Inc., Product Code Number SOL2412)
²⁾PVK ... (Poly(N-vinylcarbazole), manufactured by Tokyo Chemical Industry Co., Ltd., Product Code Number 79TPC-IC)

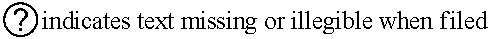

It can be seen from Table 1 that the light-emitting electrochemical cells of Examples 1 and 2, each having a light-emitting layer containing PFO-spiro (Poly[(9,9-dioctylfluorenyl-2,7-diyl)-alt-co-(9,9′-spirobifluorene-2,7-diyl)]) as a polymer material and, as a light-emitting material, a compound having a pyrromethene skeleton, exhibit a higher luminance of emitted light than the light-emitting electrochemical cell of Comparative Example 1, having a light-emitting layer not containing the compound.

In addition, it can be seen from FIG. 3 that a larger amount of a current flows on a lower voltage side in the light-emitting electrochemical cells of Examples 1 and 2, each having a light-emitting layer containing, as a light-emitting material, a compound having a pyrromethene skeleton than in the light-emitting electrochemical cell of Comparative Example 1, having a light-emitting layer not containing the compound. This means that doping of the light-emitting material is more facilitated in Examples 1 and 2 than in Comparative Example 1.

Moreover, it can be seen from FIG. 4 that Examples 1 and 2 are more excellent in the light emission efficiency than Comparative Example 1 when compared at the same voltage.

Furthermore, it can be seen from FIG. 5 that the light-emitting layer in the light-emitting electrochemical cell of Example 1 has a transmittance of 82.3% at the maximum absorption wavelength in the wavelength region of 450 nm or more and 800 nm or less and is colorless and transparent.

It can be seen from Table 1 that the light-emitting electrochemical cells of Examples 3, 4, and 5, each having a light-emitting layer containing PVK (Poly(N-vinylcarbazole)) as a polymer material and, as a light-emitting material, a compound having a pyrromethene skeleton exhibit a higher luminance of emitted light than the light-emitting electrochemical cell of Comparative Example 2, having a light-emitting layer not containing the compound.

In addition, it can be seen from FIG. 6 that a larger amount of a current flows on a lower voltage side in the light-emitting electrochemical cells of Examples 3 and 5, each having a light-emitting layer containing, as a light-emitting material, a compound having a pyrromethene skeleton than in the light-emitting electrochemical cell of Comparative Example 2, having a light-emitting layer not containing the compound.

Moreover, it can be seen from FIG. 7 that Examples 3, 4, and 5 are more excellent in the light emission efficiency than Comparative Example 2 when compared at the same voltage.

Furthermore, it can be seen from FIG. 8 that the light-emitting layer in the light-emitting electrochemical cell of Example 5 has a transmittance of 88.3% at the maximum absorption wavelength in the wavelength region of 450 nm or more and 800 nm or less and is colorless and transparent.

### INDUSTRIAL APPLICABILITY

According to the present invention, a light-emitting electrochemical cell that emits light with a high light emission efficiency and a high luminance is provided.

1. A light-emitting electrochemical cell comprising:
a light-emitting layer comprising: a polymer material having a function of transporting electrons and holes; a light-emitting material that emits light by receiving the holes and the electrons from the polymer material or emits light due to excitons generated by combination of the holes and the electrons on the polymer material; and an electrolyte; and
an electrode disposed on each face of the light-emitting layer, wherein
the light-emitting material is a compound having a pyrromethene skeleton.

2. The light-emitting electrochemical cell according to claim 1, wherein the light-emitting layer is colorless and transparent in a visible light wavelength region in a state where voltage is not applied.

3. The light-emitting electrochemical cell according to claim 1, wherein the light-emitting material is a complex of the compound having the pyrromethene skeleton.

4. The light-emitting electrochemical cell according to claim 3, wherein the light-emitting material is a compound having a structure represented by formula (1): 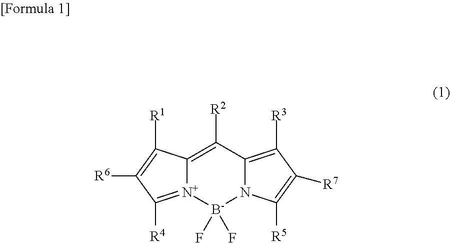
wherein R¹ to R⁷ are the same or different from one another and each independently represent a hydrogen atom or an alkyl group.

5. The light-emitting electrochemical cell according to claim 1, wherein the polymer material is colorless and transparent in a visible light wavelength region.

6. The light-emitting electrochemical cell according to claim 5, wherein the polymer material is a compound having a fluorene skeleton or a compound having a carbazole skeleton.

7. The light-emitting electrochemical cell according to claim 1, wherein the electrolyte is an ionic compound.

8. A composition for forming a light-emitting layer of a light-emitting electrochemical cell, the composition comprising:
a polymer material having a function of transporting electrons and holes;
a light-emitting material that emits light by receiving the holes and the electrons from the polymer material or emits light due to excitons generated by combination of the holes and the electrons on the polymer material; and
an electrolyte, wherein
the light-emitting material is a compound having a pyrromethene skeleton.
